(19) United States
(12) Patent Application Publication
(10) Pub. No.: US 2009/0108472 A1
(43) Pub. Date: Apr. 30, 2009

(54) WAFER-LEVEL UNDERFILL PROCESS USING OVER-BUMP-APPLIED RESIN

(75) Inventors: Claudius Feger, Poughkeepsie, NY (US); Nancy C. LaBianca, Yalesville, NY (US)

Correspondence Address: SCULLY, SCOTT, MURPHY & PRESSER, P.C., 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 11/926,634

(22) Filed: Oct. 29, 2007

(51) Int. Cl. H01L 21/58; H01L 23/12

(52) U.S. Cl. 257/782; 438/113; 257/E21.499; 257/E23.135

(57) ABSTRACT

A process of fabricating wafer-level underfilled microelectronic packages using over-bump application of a self-fluxing resin to a wafer, b-staging of the resin, dicing of the coated wafer, and joining the diced chips to substrates producing wafer-level underfilled microelectronic flip-chip packages. Moreover, provided are microelectronic packages, which are produced in accordance with the inventive process.

### BACKGROUND OF THE INVENTION

1. Field of the Invention

The present invention relates to a process of fabricating wafer-level underfilled microelectronic packages using over-bump application of a self-fluxing resin to a wafer, b-staging of the resin, dicing of the coated wafer, and joining the diced chips to substrates producing wafer-level underfilled microelectronic flip-chip packages. Moreover, the invention is further directed to the provision of microelectronic packages, which are produced in accordance with the inventive process.

Flip Chip technology is the fastest growing chip interconnect technology today because it allows for very large numbers of I/Os. Thus the footprint of chips with low numbers of I/O's can be made very small. This also holds true for associated electronic packages, such as chip-scale packages.

A major advantage of flip chip technology resides in that it can utilize the total chip area in order to provide the I/O connections, while contrastingly, wire bonding uses only the chip periphery. However, a disadvantage of flip chip technology consists of in that stresses which arise from a thermal mismatch between the silicon (chip) thermal expansion coefficient (CTE) and that of the substrate are fully borne by the solder bumps (C4s) that are used to effect the interconnections between chip and substrate.

In order to ameliorate or possibly even eliminate such stresses, flip chip packages are usually underfilled, i.e., a resin is placed between the chip and the substrate and resultingly acts as an encapsulant of the solder bumps and an adhesive between chip and substrate. The effect of such underfills resides in that the long-term reliability of underfilled flip chip packages is greatly enhanced compared to their counterparts which are not underfilled.

Underfills can be applied by either capillary flow, by using a so-called no-flow process, or by wafer-level applied processes. There are several wafer-level applied underfill processes, among them the Wafer-level Underfill (WLUF) Process which uses an over-bump applied resin, that is then b-staged, the wafer is then diced to singulate chips, and finally the chips are joined to substrates.

2. Discussion of the Prior Art

The foregoing process is generally described in Buchwalter, et al., U.S. Pat. No. 6,919,420 B2, which is commonly assigned to the present assignee, and the disclosure of which is incorporated herein in its entirety, wherein there is employed a reworkable thermoset acid-cleavable acetal and ketal based epoxy oligomers, which can be B-staged into a tack free state. The process described in that patent also covers non-reworkable thermosets.

Buchwalter, et al., U.S. Pat. No. 6,924,171 B2, which is commonly assigned to the present assignee, and the disclosure of which is incorporated herein in its entirety, disclose a similar aspect as the preceding patent which provides for a method of fabricating microelectronic interconnection structures, as well as the structures formed by the methods for improving manufacturing throughput for assembling flip chip semiconductor devices, and wherein oligomers may be employed, as in the preceding U.S. patent to Buchwalter, et al., U.S. Pat. No. 6,919,420 B2.

The publication “A Wafer-level Underfill Process for Flip-chip Packaging”, C. Feger, et al., Proc. IMAPS Flip Chip Tech; 2003, also discloses a wafer-level underfill process for flip chip packaging.

### SUMMARY OF THE INVENTION

In order to improve upon the state-of-the-technology in the provision of WLUF processes, according to the present invention, the foregoing process has been refined so as to render it more useful and efficient in connection with various applications thereof in the electronics industry.

Pursuant to the invention, a novel WLUF process resides in employing wafers that have solder bumps of essentially equal height, such as are obtained using the C4NP process (Controlled Collapse Chip Connection—new process), as is known in the prior art. This process allows for the provision of wafers in which the bump height is very uniform, considerably more so than in plated bumps. The presence of uniform bump height is advantageous in the WLUF process since it ensures that all bumps are coated to a uniform height. This facilitates that the thickness of the WLUF material through which the bumps require to be pushed through in order to make contact with the pads of the substrate, can be selected so as to be uniform. It further ensures that substantially all bumps will make contact with the corresponding substrate pads after the bumps have pushed through the coating. Moreover, the coating of the bumps with the WLUF material protects the bumps from excessive oxidation thereof.

Another advantage obtained by the present invention is to improve the WLUF process by employing wafers which were first tested prior to the wafer-level underfill (WLUF) material being applied to the bumped wafer in a manner that covers the majority of the bumps. This is accomplished by using methods known in the field to identify known-good dies.

The present invention further enables the achievement of an excellent degree of underfill adhesion by cleaning of the wafer before WLUF application. For example, a chip is normally cleaned after joining it to the substrate through using a flux to allow for C4 reflow. This cleaning step is difficult, particularly for small C4 bump sizes and large chips, since it is difficult to get the cleaning solutions into and out of small gaps. However, cleaning is absolutely necessary to be able to ensure good underfill adhesion, since without the presence of good adhesion, the reliability of the package containing the underfill is severely limited. Cleaning steps that are taken may involve cleaning with diluted acids, such as sulphuric acid, washing with an aqueous detergent solution followed by a DI rinse and rinsing with IPA, and/or oxygen plasma etching. In the WLUF process pursuant to the current invention, a bumped wafer is prepared for WLUF deposition by cleaning the wafer after bumping through processes that are typical for after bump and/or after solder join operations; whereby the wafers are then baked in order to remove volatiles from the surface and/or the passivation layer (particularly if there is used a polymeric passivation layer, such as photosensitive polyimide) just before application of the WLUF material, so that the bumps are largely coated by a layer of WLUF material.

Moreover, the present invention produces wafers that are protected by the WLUF material during wafer thinning and during subsequent handling. Since wafers are often thinned down to between 300 and 30 microns they tend to become quite fragile. Adding an organic, b-staged resin with a modulus of about 0.5-1 GPa and a thickness that exceeds the height of the bumps by 1-100 μm, imparts a significant degree of robustness to the wafer, and thereby decreases possible damage due to handling. The B-staged WLUF coating also protects the extremely fragile chip interconnect structure; an aspect that may be particularly advantageous in the development of future, low-k interlayer dielectric interconnects, whereas the WLUF also protects the solder bumps from excessive oxidation during storage.

Finally, chips, which are protected by a WLUF material, enjoy the benefit of the underfill already during the first cool down after chip join. Fragile low-k dielectric interconnect structures are easily broken during this first cool down through the stresses imparted by the CTE mismatch of the chip and substrate, however, since the WLUF material substantially or fully cures during chip join it provides the function of the underfilling extending reliability and life expectancy ab initio.

Accordingly, it is an object of the present invention to provide an improved wafer-level underfill process in the fabrication of microelectronic packages.

A more specific object of the invention resides in the provision of an improved wafer-level underfill process utilizing an over-bump application of a self-fluxing resin to a wafer, particularly as employed in the flip-chip technology.

Still another object of the present invention is to provide a microelectronic package employing the improved wafer-level underfill process as disclosed herein.

### BRIEF DESCRIPTION OF THE DRAWINGS

Reference may now be made to the following detailed description of the invention, taken in conjunction with the accompanying drawings; in which:

FIG. 1a discloses a schematic representation of a plated non-uniformily sized bump structure on a chip with B-stage wafer-level applied over bump underfill (WLUF);

FIG. 1b illustrates a non-wet bump connection caused by non-uniform bump size and the inclusion of pockets of air obtained after chip to substrate joining of such a chip;

FIG. 2a illustrates a schematic of a chip with non-uniformly bumped solder balls, which are coated by wafer-level-applied, B-staged, over-bump underfill (WLUF);

FIG. 2b illustrates the package after vacuum assisted chip to substrate joining, which does not exhibit any air inclusions but still exhibits the non-wet;

FIGS. 3a and 3b illustrate, respectively, uniformly sized solder bumps WLUF process steps pursuant to the present invention;

FIG. 4 illustrates, in an exploded view, a Step 1 of wafer bumping using C4NP and in a Step 2 wafer cleaning followed by uniform coating of bumped wafer with WLUF;

FIG. 5 illustrates, in an exploded view, wafer dicing, and then chip joining while minimizing any voids;

FIGS. 6a and 6b illustrate, in an exploded view, the sequence of steps in producing the joining thereof in more detail;

FIG. 7a illustrates, diagrammatically, in an exploded view, cleaning to remove flux residue and providing capillary underfill;

FIG. 7b illustrates steps in the preparation of the surface and application of underfill to the wafer;

FIG. 8a illustrates unprotected C4 solder balls;

FIG. 8b illustrates C4 solder balls protected by WLUF;

FIG. 9a illustrates the joining and cooling steps with the C4 bumps not being protected by WLUF; and

FIG. 9b illustrates the joining and cooling steps with the C4 bumps being protected by the WLUF pursuant to the invention.

### DETAILED DESCRIPTION OF THE PREFERRED EMBODIMENTS

Throughout the several drawing views, elements and structures which are similar or identical to each other, will be designated with the same reference numerals.

Referring in specific detail to the drawings, the inventive over-bump wafer-level underfill process requires that the WLUF (wafer-level underfill) material 10 is applied to a fully bumped wafer 12 so that a layer 14 of the WLUF material covers the solder bumps 16, 18. If the WLUF layer 14 is uniform and flat, irrespective if the solder bumps 16, 18 are different in size, and does not show large peaks and valleys, little or no air is entrapped during the subsequent joining of singulated WLUF coated chips to substrates. Air entrapment is undesirable since it reduces the reliability of the finished semiconductor package 20.

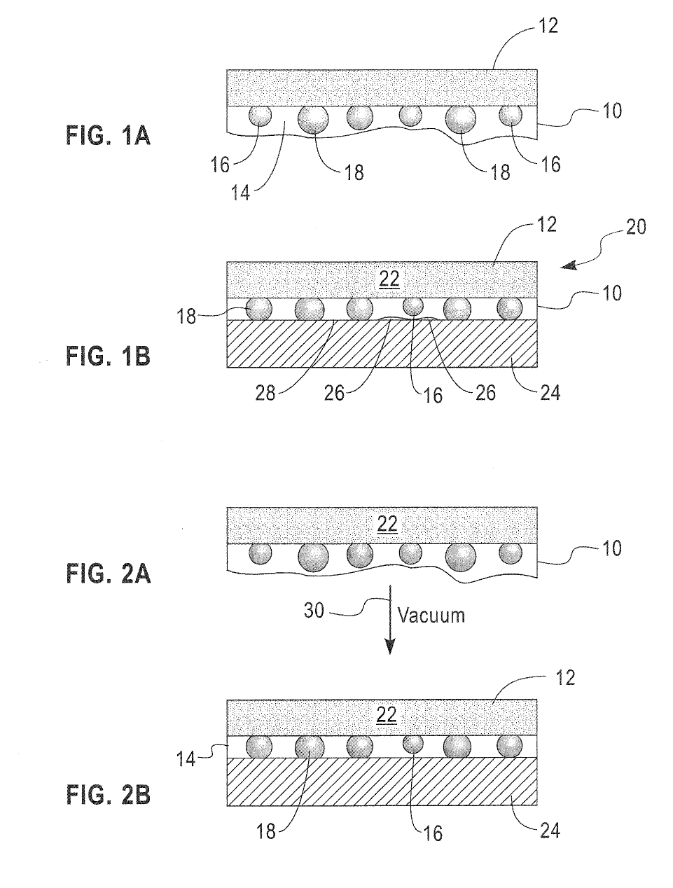

Plated bumps 16, 18 tend to exhibit significant bump height variations, as shown in FIG. 1a. When a WLUF material coats wafers 12 with such plated bumps 16, 18 and chips 22 obtained from such a coated wafer 12 are joined to a substrate 24, air inclusions 26 at the substrate—underfill interface 28 are likely to occur, as shown in FIG. 1b. Further smaller bumps 16 will not wet the substrate pad which may cause an open circuit and a fail of the package.

It is possible to avoid these air inclusions 26 or pockets by using a vacuum during joining 30, as shown in FIGS. 2a and 2b during a chip joining process. However, so-called pick-and-place tools, which can provide a local vacuum, are currently not available commercially but are under development. It is possible to avoid these air inclusions also by applying a drop of a thermosetting material that may be the substantially unfilled WLUF material 10 at the center 32 of either the C4 pad array of the substrate 24 (preferred), or of the chip 22 with a b-staged WLUF material layer 14, whereby the drop has to be substantially solvent free before the joining process in order to avoid any inclusion of solvent. This can be achieved by either providing a solvent-free version of the underfill 10 that is applied by heating the material above the Tg, and extruding the material onto the chip 22 or substrate 24, by applying the same solution used for spin-application and then using b-stage conditions to dry the drop, or by using a substantially unfilled version of the WLUF material or of a similar material. The drop aids in excluding air 26 since upon joining it will be pushed out to the chip edge 22, while driving air in front thereof to the outside.

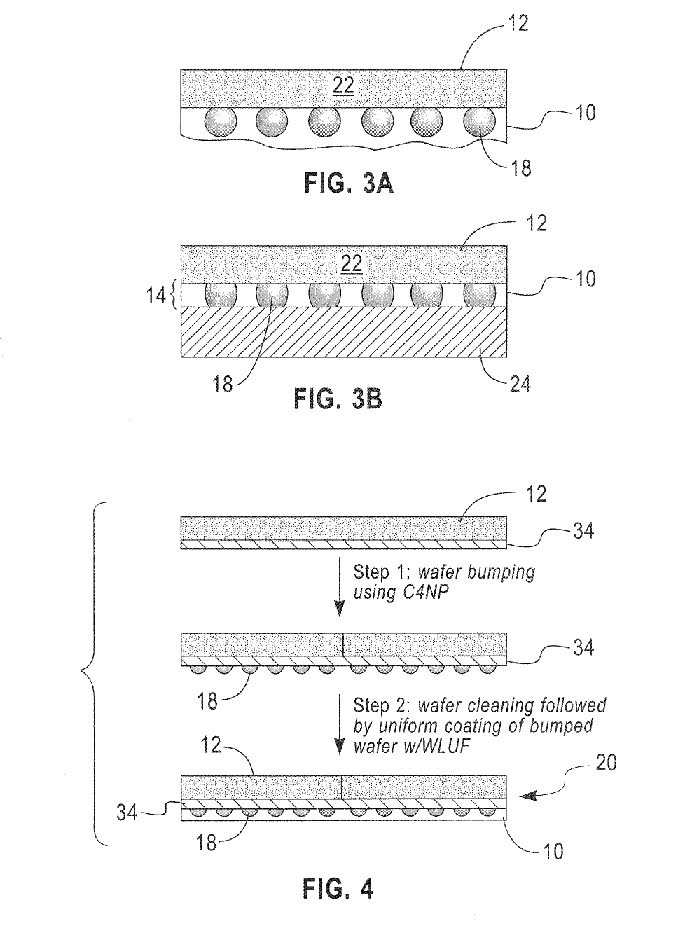

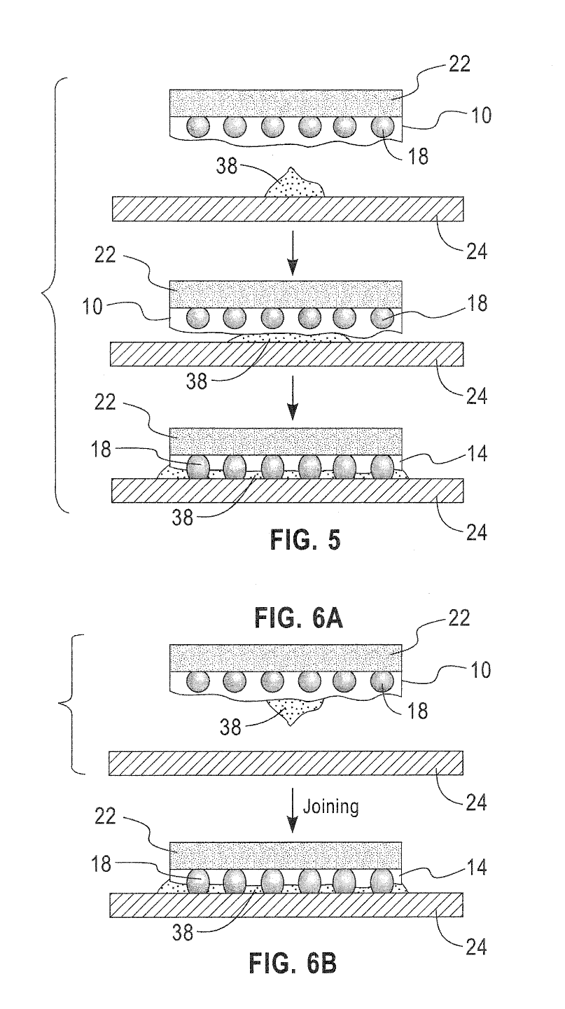

It is advantageous for the WLUF process to be conducted with the wafer 12 having uniform size balls 18, as shown in FIGS. 3a and 3b, such as are created with a C4NP process, as mentioned since the size uniformity ensures that all solder connections to the substrate pad will be made. Experiments have shown that C4NP bumped wafers coated with a WLUF material 10 achieved 100% electrical connectivity after joining of WLUF coated chips to substrates. Using the described process precautions and wafers with uniform bumps and applied WLUF material and chips which are obtained from such wafers by dicing, as in FIG. 4, offer the best path to obtaining reliable, WLU-filled semiconductor packages 20.

Once a WLUF material 10 coats a wafer 12, the solder bumps 16, 18 are covered by a layer of a dielectric insulator. This means that electrical connections can only be made during the joining process. An advantage of that situation resides in that the solder bumps 16, 18 are protected by the WLUF material 10 from severe oxidation and from handling damage which may be particularly severe with a fragile low-k interlayer dielectric. A drawback of the fact that the bumps are coated is that alignment of both wafers during dicing and chips during chip to substrate joining may be somewhat more difficult.

In a wafer 12 coated by a WLUF layer 10, the solder bumps 16, 18 are covered by a dielectric insulator, whereby this precludes testing the functionality of chips prior to dicing. This problem can be avoided by testing the wafers 12 prior to application of the wafer-level underfill (WLUF) material 10.

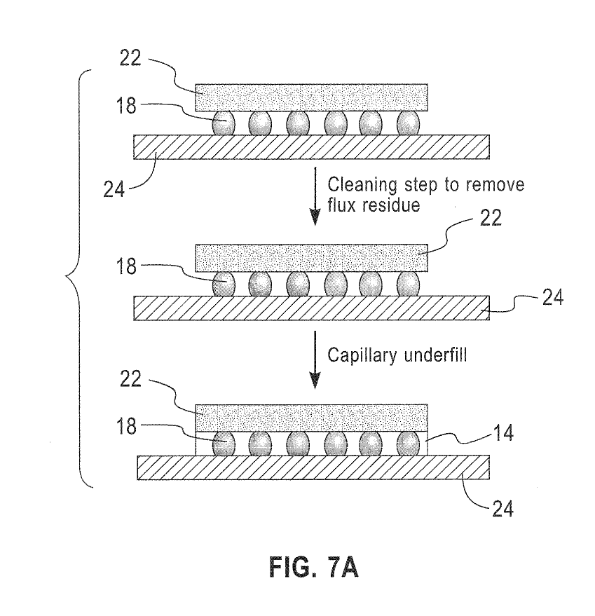

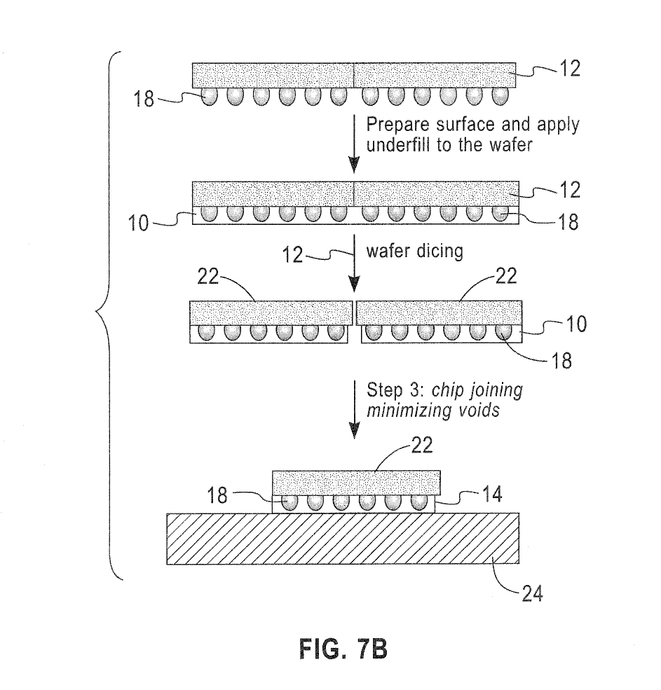

A major factor influencing the reliability of flip chip packages 20 is the adhesion of the underfill 10 to all surfaces and particularly to a chip passivation layer 34, as shown in FIG. 4. Excellent adhesion is achieved usually by cleaning the package 20 after chip joining prior to underfilling the chip. This cleaning step, which removes flux residue and any other contaminants, is absolutely necessary to ensure good underfill adhesion. Cleaning steps may involve cleaning with diluted acids such as sulphuric acid, washing with an aqueous detergent solution followed by DI rinse and rinsing with IPA, and/or oxygen plasma etching. Cleaning becomes increasingly more difficult as the chip size increases, the C4 bump pitch decreases, the bump density increases and the gap between chip and substrate decreases. This problem is solved using the WLUF process by cleaning the wafer 12 before WLUF application and the substrate 24 before joining. Hereby, as illustrated in FIGS. 7a and 7b, there is represented the cleaning process in removing flux residue and providing capillary underfill. The joining is shown in drawing FIGS. 6a and 6b.

In order to prepare the bumped wafer 12 in the WLUF process the passivation layer 34 is baked out using standard processes known to those in the field. A cleaning step using one of the above methods may be incorporated before the baking step. If the WLUF process is incorporated in the Far Back End of Line (FBEOL) process flow the last step of which often is a surface cleaning step, no further cleaning is necessary and the WLUF material 10 can be spun on and b-staged as one of the last steps of the FBEOL process. This is desirable since the WLUF layer protects the wafer 12 during wafer thinning and during subsequent handling.

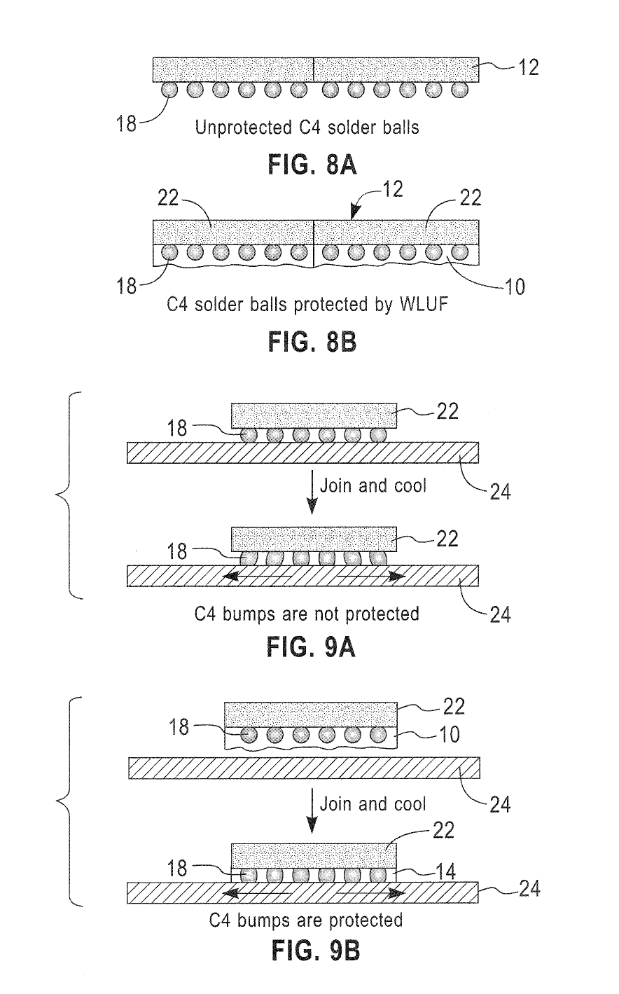

Since wafers are often thinned down to 300 to 30 μm they become quite fragile. Adding an organic, b-staged resin 38 with a modulus of 0.1-1 GPa and a thickness that exceeds the height of the solder bumps 18 by 1-100 μm provides significant robustness to the wafer 12 and decreases handling damage. It is advantageous to apply the WLUF coating and b-staging same before wafer thinning. The wafer can then be placed with the b-staged WLUF side onto a polishing pad such as known to those skilled in the art. Thinning can then proceed. A further advantage of this method is that wafers can be bumped before thinning avoiding handling of thin fragile wafers during the bumping process. The b-staged WLUF coating 10 also protects the very fragile chip interconnect structure; something that is particularly advantageous in low-k interlayer dielectric interconnects. Also the WLUF protects the solder bumps 18 from excessive oxidation during storage. This may be as represented in FIGS. 4, 8a and 8b of the drawings.

Chips, which are protected by a WLUF material, derive the benefit of the underfill already during the first cool down after chip join. Experiments have shown that the WLUF process can indeed protect the fragile low-k dielectric interconnect structure which without this process are easily broken during this first cool down through the stresses imparted by the CTE mismatch of the chip and substrate. This distinction is clearly represented in, respectively, FIGS. 9a and 9b of the drawings. Since the WLUF material cures substantially or fully during chip join it provides the function of underfilling in extending reliability and lifetime from the get go.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but to fall within the spirit and scope of the appended claims.

What is claimed is:

1. A process of fabricating wafer-level underfilled microelectronic packages, said process comprising:
a) having a wafer provided with solder bumps of substantially uniform solder height arranged on one surface thereof;
b) coating the surface of the wafer with an over-bump applied wafer-level underfill material (WLUF);
c) b-staging the WLUF material;
d) dicing said WLUF coated and b-staged wafer into singulated, WLUF coated chips;
e) aligning a substrate opposite said coated solder bumps and facing the surfaces of said chips;
g) positioning the surfaces of the WLUF-coated chips into contact with said facing substrate surface and applying pressure and temperature until said bumps penetrate through said WLUF coating coming to rest on the appropriate substrate pad; and heating said structure until the solder melts and the chip is electrically joined to the substrate through the solder bumps.

2. A process as claimed in claim 1, wherein said solder bumps are comprised of a plurality of differently sized solder bumps.

3. A process as claimed in claim 1, wherein said solder bumps are comprised of a plurality of uniformly sized solder bumps.

4. A process as claimed in claim 3, wherein the uniformly sized solder bump height is attained by a C4NP process.

5. A process as claimed in claim 1, wherein said b-staged underfill material contains a self-fluxing resin.

6. A process as claimed in claim 1, wherein joining of the chip to said substrate process is carried out in a vacuum.

7. A process as claimed in claim 1, wherein the surface of said wafer is cleaned prior to application of the over-bump applied wafer-level underfill.

8. A process as claimed in claim 7, wherein said cleaning is effectuated through application of a diluted acid and implementing a subsequent rinsing.

9. A process as claimed in claim 8, wherein said diluted acid comprises sulfuric acid.

10. A process as claimed in claim 7, wherein said cleaning is effectuated through washing with isopropyl alcohol and subsequent rinsing.

11. A process as claimed in claim 7, wherein said cleaning is effectuated through an oxygen a plasma process.

12. A process as claimed in claim 1, wherein during joining air entrapped in the space between the chip and substrate surfaces being brought together is displaced outward towards the edge of the chips by the underfill material.

13. A process as claimed in claim 12, wherein said entrapped air is displaced outward by a small amount of a resin which is deposited on the substrate side opposite said WLUF coated chips.

14. A process as claimed in claim 13, wherein the resin consists of the unfilled WLUF resin, or of a material, which is substantially an equivalent of the WLUF material.

15. A process as claimed in claim 13 wherein the resin possesses a good fluxing behavior, and good adhesive properties.

16. A process as claimed in claim 13, wherein the resin is heated to achieve a flow thereof.

17. A process as claimed in claim 13, wherein the resin is placed in the center of the solder bump array.

18. A process as claimed in claim 13, wherein the small amount of the resin is applied in a pattern such as a line or a cross-shape on said surface.

19. A process as claimed in claim 13, wherein said small amount of resin is placed on the b-staged WLUF of the chip side opposite said substrate.

20. A process as claimed in claim 1, wherein a stress acting on the solder bumps is reduced during cool down after chip to substrate joining.

21. A process as claimed in claim 1, wherein the solder bumps are protected from oxidation.

22. A structure which is obtained by the process according to claim 1.

23. A process of fabricating thinned, bumped and wafer-level underfill coated semiconductor wafers, said process comprising:
a) a wafer having solder bumps of substantially uniform solder height being arranged on one surface thereof;
b) coating the surface of the wafer with an over-bump applied wafer-level underfill material (WLUF);
c) b-staging the WLUF material; and
d) thinning said wafer.

24. A structure obtained by dicing the wafer of claim 23 into chips and joining said chips to substrates.
